(19) United States
(12) Patent Application Publication
(10) Pub. No.: US 2008/0030620 A1
(43) Pub. Date: Feb. 7, 2008

(54) Analog front end circuit and image processing device for video decoder

(75) Inventors: Jui-Yuan Tsai, Tainan City (TW); Wen-Chi Wang, Hsi Luo Town (TW); Chang-Shun Liu, Taipei City (TW)

Correspondence Address: BIRCH STEWART KOLASCH & BIRCH, PO BOX 747, FALLS CHURCH, VA, 22040-0747, US

(73) Assignee: REALTEK SEMICONDUCTOR CORP.

(21) Appl. No.: 11/878,890

(22) Filed: Jul. 27, 2007

(30) Foreign Application Priority Data
Aug. 4, 2006 (TW) 095128586

(51) Int. Cl. H03M 1/12

(52) U.S. Cl. 348/572; 341/155

(57) ABSTRACT

An analog front end circuit is provided, which comprises at least one converting circuit. Each converting circuit further comprises a clamper, a low-pass filter, an input buffer and a sigma-delta analog-to-digital converter. By using the sigma-delta analog to digital converter, the invention not only increases the resolution, but reduces the order of an anti-aliasing filter, therefore reducing the size and the power consumption of the analog circuit.

### BACKGROUND OF THE INVENTION

1. Field of the Invention

The invention relates to display systems, and more particularly, to an analog front end (AFE) circuit and an image processing device for video decoders.

2. Description of the Related Art

Ever since the 20th century, the development of the television technology and its applications has proven that it is now part of human life and center of entertainment. Due to the advancement of the display technology in recent years, providing massive information and high-definition images becomes the focus of development for the next generation of the television industry. FIG. 1 shows a schematic diagram of a conventional television system and its video data source. Referring to FIG. 1, a video data source system 110 sends video data in an analog format to a television system 120 for displaying video frames. Although digitized transmission interfaces are already available, analog transmission interfaces are still most widely adopted.

There is a wide variety of types of video data sources for television systems, including examples such as DVD players, set top boxs, and even various game consoles. In general, a video encoder 112, included as a commonly seen component of the video data source system 110, is used to encode image data. Next, by means of a digital to analog converter (DAC) 114, an encoded digital signal is converted into an analog signal, and then the analog signal is transmitted.

The television system 120, such as a LCD TV, which has become a prominent application, or other flat panel television systems or a digital television system, receives the analog signal fed from the video data source 110 via a transmission medium (e.g., a cable). An analog to digital converter (ADC) 124 converts the analog signal into a digital format, and then a video decoder 122 performs a decoding operation for further image processing and displaying.

Among various types of video encoding formats, composite video signal (CVBS), separate video signal (YC), and component video signal (YPrPb) are among the most popular. Therefore, an analog transmission interface for transmitting video signals between the video data source system 110 and the television system 120 can be chosen from several types. For example, a composite video connector is used to transmit the CVBS signal; a separate video (S-video) connector is used to transmit the YC signals; a component video connector is used to transmit the YPrPb signals. Among the above-mentioned video encoding formats, the CVBS signal, the Y signal of the separate video signal, and the Y signal of the component video signal all contain, in addition to a video information component, a synchronization component for performing synchronization operations.

In general, television systems have minimal requirement on the resolution of the video information component contained in the analog video signal, to ensure the displayed image quality; this means that the ADC 124 must be able to support an effective number of bits (ENOB) greater than a certain amount. Generally speaking, the more the ENOB of the ADC is, the better the image quality decoded by the video decoder becomes. Nevertheless, due to manufacturing process limitations, such as the difficulty of capacitor matching and impedance matching, the more the ENOB of the ADC is, the more the design complexity and manufacturing cost increase.

The ADC 124 in the television system 120 is mostly implemented as a pipelined ADC. Typically, the pipelined ADC has a sampling rate of 27 MHz or 54 MHz and an ENOB of about 8-12 bits. Due to its architecture limitations, the pipelined ADC is not able to achieve a higher resolution by using over-sampling technique. This is because the ENOB of the pipelined ADC is normally limited by both the capacitor mismatch inherent in manufacturing process and the thermal noise generated by capacitors during operation without the use of trimming and calibration techniques. In other words, the better the process control and the more accurate the capacitance value is, the higher the resolution of the pipelined ADC will be. Therefore, for the pipelined ADC, in order to achieve a higher resolution, using calibration techniques to overcome capacitor mismatch is a usually adopted solution. However, in case where calibration techniques are not allowed to be used, other solutions to address the above-identified problems are needed, in order to increase the resolution of image signals and reduce hardware cost.

### SUMMARY OF THE INVENTION

In view of the above-mentioned problems, an object of the invention is to provide an analog front end (AFE) circuit, which uses a sigma-delta ADC in order to increase image resolution.

To achieve the above-mentioned object, the AFE circuit of the invention is used to receives at least one analog image signal and generate at least one digital signal, comprising: a clamper for adjusting a DC voltage level of an analog image signal to generate a restored signal; a low-pass filter for receiving the restored signal, attenuating high-frequency noise and generating a filtered signal; an input buffer for buffering the filtered signal and generating a buffering signal; and, a sigma-delta analog to digital converter having a positive input terminal and a negative input terminal, one of which receives the buffering signal and the other of which receives a comparing voltage, wherein the sigma-delta analog to digital converter converts a voltage difference between the two input terminals into the digital signal according to a clock signal.

By using the sigma-delta ADC, the invention achieves a higher image resolution; in addition, one of the advantages is that the invention integrated with an over-sampling technique reduces not only the order of an anti-aliasing filter, but also the size and the power consumption of the analog circuit.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 shows a diagram of a conventional television system and its video data source.

FIG. 2 is a schematic circuit diagram illustrating an image processing device according to an embodiment of the invention.

FIG. 3A is a noise spectrum diagram with a signal bandwidth of f_{S}/2 and a sampling rate of f_{S}.

FIG. 3B is a noise spectrum diagram with a signal bandwidth of f_{S}/2 and a sampling rate of K·f_{S}.

FIG. 3C is a noise spectrum diagram after noise shaping is introduced into FIG. 3B.

FIG. 4A is the frequency response of an anti-aliasing filter integrated with an ADC, with a signal bandwidth of f_{CLK}/2 and a sampling rate of f_{CLK}.

FIG. 4B is the frequency response of an anti-aliasing filter integrated with an ADC, with a signal bandwidth of f_{CLK}/(2·K) and a sampling rate of f_{CLK}.

### DETAILED DESCRIPTION OF THE INVENTION

The AFE circuit and image processing device for video decoder of the invention will be described with reference to the accompanying drawings.

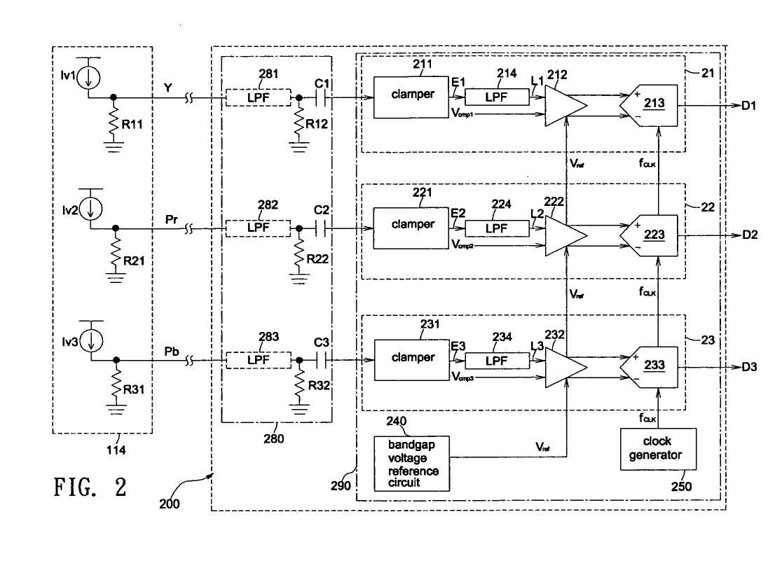

FIG. 2 is a schematic circuit diagram illustrating an image processing device according to an embodiment of the invention.

Referring to FIG. 2, the image processing device 200 of the invention comprises an input unit 280 and an AFE circuit 290. In this embodiment, an analog image signal outputted from the ADC 114 in the video source system 110 is sent to the input unit 280 via a cable and then to the AFE circuit 290. Here, the image processing device 200 is a portion of either a television system (not shown) or other video display systems. The AFE circuit 290 is disposed in a video decoder (not shown) while the input unit 280 is disposed on a printed circuit board.

For an analog image signal that is delivered into the input unit 280, its video encoding format contains both a video information component and a synchronization component, such as the CVBS signal, the YC signals, or the YPrPb signals. It should be understood, however, that the invention is not limited to these particular few video encoding formats described above, but fully extensible to any existing or yet-to-be developed video encoding formats. Hereinafter, the image processing device 200 will be described in detail with the YPrPb signals being taken as an example. The image processing device 200 receives three analog image signals Y, Pr, and Pb, performs DC level restoring and generates three digital signals D1, D2, and D3.

The analog image signals Y Pr, and Pb outputted from the DAC 114, represented by three current source (Iv1, Iv2, Iv3), are delivered to the AFE device 290 for performing analog to digital conversion via the input unit 280. It should be appreciated by those skilled in the image processing art that the transmission lines in FIG. 2 can be implemented by various existing or creative methods, including but not limited to any wired or wireless medium. In this embodiment, a low-order low-pass filter (281, 282, 283) for attenuating noise, a termination resistor (R12, R22, R23) (approximately 75Ω) for resolving the reflections of signals, and an AC coupling capacitor (C1, C2, C3) for removing the DC offset of the analog image signal are installed in each signal path in the input unit 280, respectively. The DC voltage level is subject to drifting after the analog image signals (Y, Pr, Pb) have been transmitted over a long transmission line. Accordingly, the low-order low-pass filter (281, 282, 283) is first used to attenuate noise, and then both the termination resistor (R12, R22, R23) and the AC coupling capacitor (C1, C2, C3) are used to remove the DC offset of the analog image signal. Finally, the clamper is used to restore the DC voltage level of the analog image signal.

According to the invention, the number of converting circuits included in the AFE circuit 290 is equal to the number of the analog image signals received by the AFE circuit 290. In this embodiment, the AFE circuit 290 comprises three identical converting circuits 21, 22, 23 so as to simultaneously process three analog image signals Y, Pr, Pb. Each of the three converting circuits 21, 22, 23 comprises a clamper (211, 221, 231), a low-order low-pass filter (214, 224, 234), an input buffer (212, 222, 232), and a sigma-delta ADC (213, 223, 233).

The clamper (211, 221, 231) receives an analog image signal (Y, Pr, Pb), restores the DC voltage level of the analog image signal, and generates a restored signal (E1, E2, E3). The low-pass filter (214, 224, 234) receives the restored signal (E1, E2, E3) and attenuates high-frequency noise to generate a filtered signal (L1, L2, L3). According to a reference voltage V_{ref}, the input buffer (212, 222, 232) buffers and then outputs both the filtered signal (L1, L2, L3) and a comparing voltage (V_{cmp1}, V_{cmp2}, V_{cmp3}). Lastly, the sigma-delta ADC (213, 223, 233) converts a voltage difference (e.g., (L1−V_{cmp1})) between two input terminals into a digital signal (D1, D2, D3) according to a clock signal f_{CLK}.

The AFE circuit 290 further comprises a bandgap voltage reference circuit 240 and a clock generator 250. The clock generator 250 supplies a periodic clock signal f_{CLK} to the sigma-delta ADC (213, 223, 233) for sampling use. Meanwhile, the bandgap voltage reference circuit 240 supplies a reference voltage V_{ref} either to the input buffer (212, 222, 232) for adjusting its gain and offset voltage, or to the sigma-delta ADC (213, 223, 233) for adjusting its full-scale voltage or bias current.

The technical background and the reason for using the sigma-delta ADC integrated with a low-order low-pass filter in this invention will be hereinafter detailed.

In general, the bandwidth of the analog image signal is approximately 6 MHz. Traditionally, sigma-delta ADCs are often used in narrow-bandwidth (for example, audio signal with bandwidth of about 20 KHz; asymmetric digital subscriber line (ADSL) signal with bandwidth of about 2.2 MHz) and high-resolution (for example, audio signal with resolution of 16 bits; ADSL signal with resolution of 13 bits) applications. In virtue of the development of analog circuit design, the bandwidth of the sigma-delta ADCs has been increased to a degree to fit video applications.

In terms of resolution, unlike the pipelined ADCs, which are limited by capacitor mismatch, the sigma-delta ADCs are mainly limited by noise, but the problem of noise can be avoided by means of the over-sampling and noise shaping architecture of the sigma-delta ADCs, thereby increasing the overall resolution.

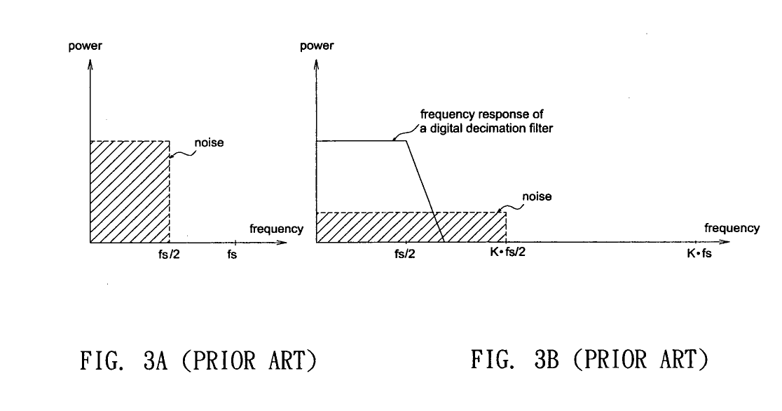

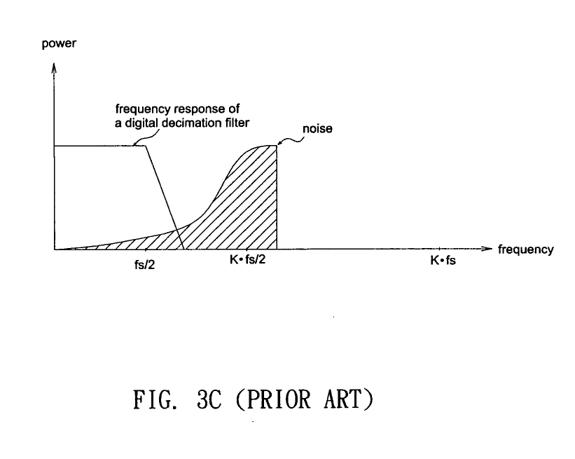

FIG. 3A is a noise spectrum diagram with a signal bandwidth of f_{S}/2 and a sampling rate of f_{S} FIG. 3B is a noise spectrum diagram with a signal bandwidth of f_{S}/2 and a sampling rate of K·f_{S}.

For an ADC with a resolution of n bits (n being a positive integer), its quantized noise power is q²/12 (q=least significant bit). When observing the noise characteristic in frequency domain, according to Nyquist sampling theorem its power spectrum density is a uniform function with a magnitude of (q·\sqrt{ƒ_{S}})/\sqrt{12} within a frequency range of −f_{S}/2˜f_{S}/2 as shown in FIG. 3A, wherein f_{S} denotes the sampling rate. While over-sampling, or up-sampling, is performed, i.e., a higher sampling rate K·f_{S} being used on the sampling of the signal with the same bandwidth of f_{S}, as shown in FIG. 3B, there will be no changes in the signal spectrum characteristic because n is not changed; however, the magnitude of the quantized noise power spectrum density is reduced (i.e., a noise floor being dropped) as the sampling rate is getting higher compared to the signal bandwidth. If the sampled signal is then processed by a digital low-pass filter, there will be no effect on the sampled signal, but a portion of the quantized noise is eliminated. As a result, signal-to-noise ratio (SNR), and consequently ENOB or resolution, are increased. Consequently, the ADC with a resolution greater than n bits is derived from the ADC with a resolution of n bits integrated with both over-sampling and low-pass filtering (or digital decimation filtering) operations; for example, the ADC resolution will be increased by one bit whenever the sampling rate is increased by four times.

FIG. 3C is a noise spectrum diagram after noise shaping is introduced into FIG. 3B.

One distinctive feature of noise shaping is to change the quantized noise power distribution, pushing most of the quantized noise into higher frequency range, as shown in FIG. 3C. As such, after the low-pass filtering (or digital decimation filtering) is performed on the sampled signal, most of the quantized noise can be eliminated, so as to increase the SNR and resolution. Therefore, the invention utilizes a sigma-delta ADC with over-sampling and noise shaping architecture to get rid of noise, accordingly increasing the SNR and the overall resolution. In practice, the overall resolution can be increased up to about 15 bits.

In terms of sampling rate, assuming that the pipelined ADC and the sigma-delta ADC have the same sampling rate f_{CLK}, then with reference to the Nyquist sampling theorem, the input signal bandwidth of the pipelined ADC must be less than or equal to f_{CLK}/2; in contrast, since the sigma-delta ADC utilizes over-sampling architecture, its input signal bandwidth needs to be less than or equal to f_{CLK}/(2·K), wherein K is a positive integer and denotes an over-sampling multiple. In sum, in the case where the pipelined ADC and the sigma-delta ADC have the same sampling rate f_{CLK}, the input signal bandwidth of the sigma-delta ADC is less than that of the pipelined ADC.

On the other hand, in the conventional AFE circuits, the front end circuit of the pipelined ADC is usually integrated with either a low-pass filter or an anti-aliasing filter, to remove aliasing effects or noise (described hereinafter). However, as the order of the anti-aliasing filter is getting higher, the filtering effect is getting better, but the hardware cost increases as well.

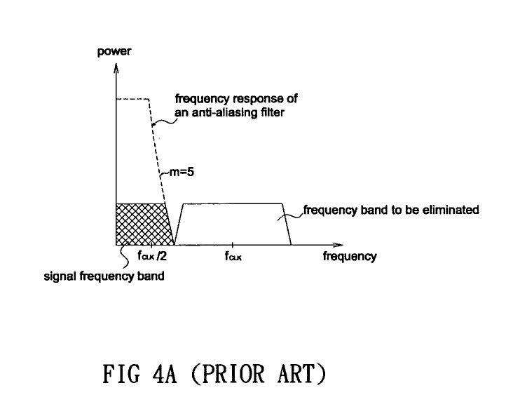

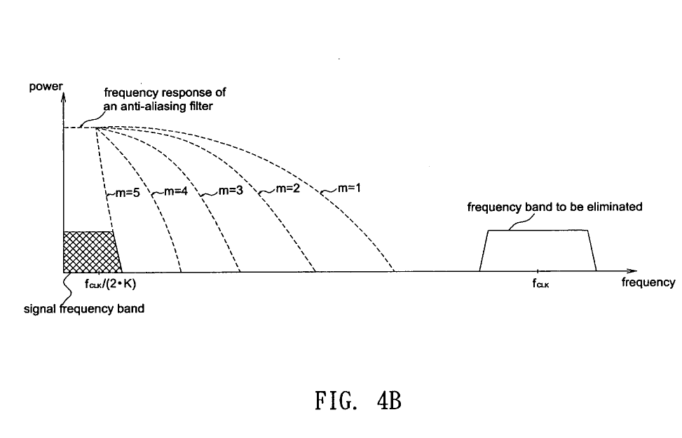

FIG. 4A is the frequency response of an anti-aliasing filter integrated with an ADC, with a signal bandwidth of f_{CLK}/2 and a sampling rate of f_{CLK}. FIG. 4B is the frequency response of an anti-aliasing filter integrated with an ADC, with a signal bandwidth of f_{CLK}/(2·K) and a sampling rate of f_{CLK}.

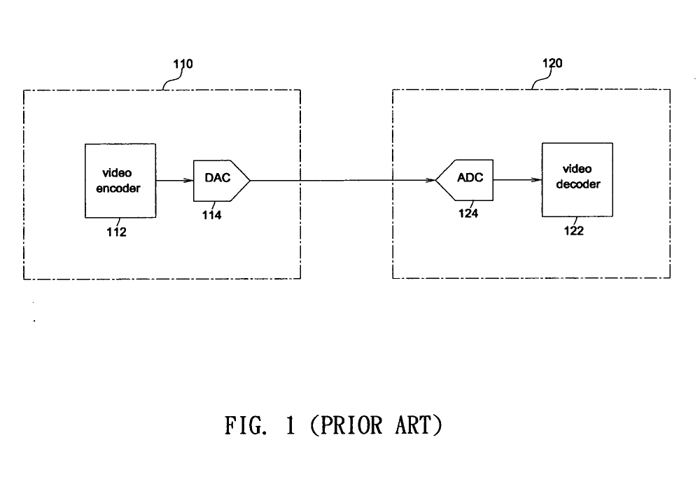

Referring now to FIGS. 1 and 4A, according to the Nyquist sampling theorem, the signal bandwidth of a pipelined ADC needs to be less than or equal to f_{CLK}/2 if its sampling rate is equal to f_{CLK}. In this case, the frequency response of the anti-aliasing filter (not shown in FIG. 1) integrated with the pipelined ADC needs to be “steeper”, which means that the order of the anti-aliasing filter needs to be higher (for example, an anti-aliasing filter with an order of m=3˜5, as shown in FIG. 4A). In contrast, when a sigma-delta ADC performs an over-sampling operation, with reference to FIGS. 2 and 4B, the frequency response of the anti-aliasing filter integrated with the sigma-delta ADC needs not be “steep”, since the signal frequency band and its replicas at each integer multiple of the sampling rate are widely separated. In other words, the order of either the low-pass filter or the anti-aliasing filter (214, 224, 234, 281, 282, 283) can be decreased (for example, an anti-aliasing filter with an order of m=1˜2, as shown in FIG. 4B). In extreme cases, the anti-aliasing filters (281, 282, 283) in the input unit 280 can even be entirely removed, therefore the dotted line representation in FIG. 2.

In sum, by using the sigma-delta ADC, the invention achieves a higher image resolution; in addition, one of the advantages is that the invention integrated with over-sampling reduces not only the order of an anti-aliasing filter, but also the size and the power consumption of the analog circuit.

While certain exemplary embodiments have been described and shown in the accompanying drawings, it is to be understood that such embodiments are merely illustrative of and not restrictive on the broad invention, and that this invention should not be limited to the specific construction and arrangement shown and described, since various other modifications may occur to those ordinarily skilled in the art.

What is claimed is:

1. An analog front end circuit for receiving at least one analog image signal and generating at least one digital signal, the analog frond end circuit comprising at least a converting circuit, each converting circuit comprising:
a clamper for adjusting a DC voltage level of the analog image signal to generate a restored signal;
a low-pass filter for receiving the restored signal, attenuating high-frequency noise and generating a filtered signal;
an input buffer for buffering the filtered signal and generating a buffering signal; and
a sigma-delta analog to digital converter having a positive input terminal and a negative input terminal, one of which receives the buffering signal and the other of which receives a comparing voltage, wherein the sigma-delta analog to digital converter converts a voltage difference between the two input terminals into the digital signal according to a clock signal.

2. The analog front end circuit according to claim 1, which is disposed in a video decoder, wherein the analog front end circuit comprises one or two or three converting circuits.

3. The analog front end circuit according to claim 1, wherein the low-pass filter is a low-order low-pass filter.

4. The analog front end circuit according to claim 1, wherein an order of the low-pass filter is one or two.

5. The analog front end circuit according to claim 1, further comprising:
a bandgap voltage reference circuit for supplying a reference voltage to both the sigma-delta analog to digital converter and the input buffer; and
a clock generator for providing the clock signal.

6. An image processing device for processing at least one analog image signal fed from a video data source system and generating at least one digital signal, comprising:
an input unit having a ground terminal for transmitting the at least one analog image signal; and
an analog front end circuit coupled to the input unit and comprising at least one converting circuit, each converting circuit comprising:
a clamper for adjusting a DC voltage level of the at least one analog image signal to generate a restored signal;
a first low-pass filter for receiving the restored signal, attenuating high-frequency noise and generating a first filtered signal;
an input buffer for buffering the first filtered signal and generating a buffering signal; and
a sigma-delta analog to digital converter having a positive input terminal and a negative input terminal, one of which receives the buffering signal and the other of which receives a comparing voltage, wherein the sigma-delta analog to digital converter converts a voltage difference between the two input terminals into the digital signal according to a clock signal.

7. The image processing device according to claim 6, which is disposed in a video decoder, wherein the analog front end circuit comprises one or two or three converting circuits.

8. The image processing device according to claim 6, wherein the first low-pass filter is a low-order low-pass filter.

9. The image processing device according to claim 8, wherein an order of the first low-pass filter is one or two.

10. The image processing device according to claim 6, wherein there is one signal path for each of the at least one analog image signal in the input unit and there is one second low-pass filter disposed in each signal path, and wherein the second low-pass filter receives the analog image signal, attenuates high-frequency noise and supplies a second filtered signal to the clamper.

11. The image processing device according to claim 10, wherein the second low-pass filter is a low-order low-pass filter.

12. The image processing device according to claim 11, wherein an order of the second low-pass filter is one or two.

13. The image processing device according to claim 6, wherein the input unit is disposed in a printed circuit board.

14. The image processing device according to claim 6, wherein the analog front end circuit further comprises:
a bandgap voltage reference circuit for supplying a reference voltage to both the sigma-delta analog to digital converter and the input buffer; and
a clock generator for providing the clock signal.

15. An analog front end circuit, comprising
a clamper for adjusting a DC voltage level of an analog signal to generate a restored signal;
a low-pass filter for receiving the restored signal, attenuating high-frequency noise and generating a filtered signal;
an input buffer for buffering the filtered signal and generating a buffering signal; and
a sigma-delta analog to digital converter having a positive input terminal and a negative input terminal, one of which receives the buffering signal and the other of which receives a comparing voltage, wherein the sigma-delta analog to digital converter converts a voltage difference between the two input terminals into a digital signal according to a clock signal.

16. The analog front end circuit according to claim 15, which is disposed in a video decoder, wherein the analog front end circuit comprises one or two or three converting circuits.

17. The analog front end circuit according to claim 15, wherein the low-pass filter is a low-order low-pass filter.

18. The analog front end circuit according to claim 17, wherein an order of the low-pass filter is one or two.

19. The analog front end circuit according to claim 15, further comprising:
a bandgap voltage reference circuit for supplying a reference voltage to both the sigma-delta analog to digital converter and the input buffer; and
a clock generator for providing the clock signal.
